(19) United States
(12) Patent Application Publication
(10) Pub. No.: US 2024/0274422 A1
(43) Pub. Date: Aug. 15, 2024

(54) SINGLE ELECTRON AND PHOTON RADIO FREQUENCY TIMER

(71) Applicants: Amur Margaryan, Yerevan (AM); Vanik Kakoyan, Yerevan (AM); Simon Zhamkochyan, Yerevan (AM); Sergey Abrahamyan, Yerevan (AM); Hayk Elbakyan, Razdan (AM); Samvel Mayilyan, Yerevan (AM); Henrik Vardanyan, Yerevan (AM); Hamlet Zohrabyan, Yerevan (AM); Lekdar Gevorgyan, Yerevan (AM); Robert Ayvazyan, Yerevan (AM); Artashes Papyan, Yerevan (AM); Garnik Ayvazyan, Yerevan (AM); John R.M. Annand, Inverness (GB); Kenneth Livingston, Glasgow (GB); Rachel Montgomery, Glasgow (GB); Patric Achenbach, Bingen am Rhein (DE); Josef Pochodzalla, Rauenberg (DE); Dimiter L. Balabanski, Sofia (BG); Satoshi N. Nakamura, Chiba (JP); Ani Aprahamian, South Bend, IN (US)

(72) Inventors: Amur Margaryan, Yerevan (AM); Vanik Kakoyan, Yerevan (AM); Simon Zhamkochyan, Yerevan (AM); Sergey Abrahamyan, Yerevan (AM); Hayk Elbakyan, Razdan (AM); Samvel Mayilyan, Yerevan (AM); Henrik Vardanyan, Yerevan (AM); Hamlet Zohrabyan, Yerevan (AM); Lekdar Gevorgyan, Yerevan (AM); Robert Ayvazyan, Yerevan (AM); Artashes Papyan, Yerevan (AM); Garnik Ayvazyan, Yerevan (AM); John R.M. Annand, Inverness (GB); Kenneth Livingston, Glasgow (GB); Rachel Montgomery, Glasgow (GB); Patric Achenbach, Bingen am Rhein (DE); Josef Pochodzalla, Rauenberg (DE); Dimiter L. Balabanski, Sofia (BG); Satoshi N. Nakamura, Chiba (JP); Ani Aprahamian, South Bend, IN (US)

(21) Appl. No.: 18/431,948

(22) Filed: Apr. 19, 2024

(30) Foreign Application Priority Data
Feb. 13, 2023 (AM) AM20230011Y

(51) Int. Cl. H01J 43/30; H01J 37/21; H01J 43/24

(52) U.S. Cl. CPC H01J 43/30; H01J 37/21; H01J 43/246

(57) ABSTRACT

The invention relates to a class of RF Timer based electron and photon vacuum recorders, particularly to single electron and photon sensitive recorders with picosecond time resolution. The RF Timer features a vacuum container housing an electron gun with a photocathode, an electron-transparent accelerating electrode, and an electrostatic lens for electron focusing. A deflecting electrode guides photoelectrons in a circular and spiral path, and a position-sensitive detector system records their positions with nanosecond electronic signals processed in real-time. The objective is to achieve single electron and photon recording with a time resolution of 10 picoseconds or better at speeds reaching several MHz and stability better than 0.2 picoseconds/h.

### FIELD OF THE INVENTION

The present invention relates to a class of radio frequency (RF) timer based electron and photon vacuum recorders, particularly single electron and photon sensitive and picosecond (ps) time resolution recorders.

### BACKGROUND OF THE INVENTION

In the present, recording of photons and electrons is performed using vacuum photomultipliers tubes (PMT), avalanche photodiodes (APD), Si photomultipliers (SiPM), or hybrid photon detectors (HPD) based on both. By recording photons and electrons, the nanosecond electrical signals from these devices also provide information about recording time, which is needed in various fields of science and engineering. With PMTs, APDs, SiPMs and HPDs, single photon and electron recording times can be determined with a resolution of about 40 ps. Recently developed detectors based on superconducting nanowires can detect single photons or electrons with a resolution of 15 ps or better. However, to operate these detectors, it is necessary to ensure a low temperature (temperature of liquid helium), which is a serious technical problem.

Conversely, it is well known that timing systems based on radio frequency (RF) fields can provide precision of the order of 1 ps or better (see e.g. E. K. Zavoisky and S. D. Fanchenko, Physical principles of electron-optical chronography, Sov. Phys. Doklady 1 (1956) 285 and A. M. Prokhorov and M. Ya. Schelev, Recent research and development in electron image tubes/cameras/systems, International Congress on High-Speed Photography and Photonics, Proc. SPIE 1358 (1990) 280).

Streak cameras, based on similar principles, are used routinely for measurements in the picosecond range (see for example D. J. Bradly, Ultra-short Light Pulses, Picosecond Techniques and Applications, in Topics in Applied Physics, 18 (1977) 17), and have found an increasing number of applications, in particular, in particle accelerators, permitting both precise measurements and instructive visualizations of beam characteristics and behavior that cannot be obtained using other beam instrumentation, (see for example K. Scheidt, Review of Streak Cameras for Accelerators: Features, Applications and Results, Proceedings of EPAC 2000, Vienna (2000) 182).

A Circular-scan Streak Tube system has been proposed for detecting, recording, and temporally resolving optical events on the order of picoseconds. Much of the investigation in this field has been conducted as part of developing a space-borne laser ranging system.

Several possible kinds of readouts for circular scan streak tubes have been considered. The Photochron HC streak tube as reported in 1984 included a phosphor screen at the output of the tube, covered by a fiberoptic faceplate. The streaked output images were recorded photographically on film. (See W Sibbett et al, “Photochron HC streak tube for 300 MHz circular-scan operation,” SPIE Vol. 491 High Speed Photography (Strasbourg 1984)). This method provides a data record length limited to a single scan.

Later, improved signal detection was reported in W. Sibbett and W. E. Sleat, “A Photochron HC Circular-scan Streak Camera with CCD Readout”, SPIE Vol. 674 High Speed Photography (Pretoria 1986), pp 543-558 and A. Finch, et al, “Electron-sensitive CCD Readout Array for a Circular-scan Streak Tube,” SPIE Vol. 591 Solid State Imagers and Their Applications (1985), pp 31-37. Both of these papers describe the Photochron HC as a system including a circular array target comprising an array of photodiodes as sensing elements and a CCD shift register to read out the resulting charge. While sensitivity was improved, this arrangement is no less limited in record length to data collected over a single circular scan of the electron beam. After one scan, it is necessary to blank the writing beam, or deflect it off of the electron-beam-sensitive portion of the target to avoid overwriting.

The article titled “Circular-scan Streak Tube with solid-state readout” by C. B. Johnson et al. in the Oct. 15, 1980, issue of Applied Optics, describes a Circular-scan Streak Tube that uses a circular photodiode array as a sensing element. The array is optically fiber-coupled to the output phosphor screen of the tube. The readout circuitry of the array is triggered by the first (start) and second (stop) laser pulses to record first and second streaked output signals, respectively. This allows for the measurement of the time between the laser pulses in a single-shot acquisition, rather than continuous recording.

The Hadland 2DR system is a commercial streak camera and readout system that was described in an article by D. L. Bowley titled “Measuring Ultrafast Pulses” in Lasers & Optronics, September 1987, pages 81-83. The Hadland 2DR target uses a rectangular area CCD array that is optically fiber-coupled to the camera. It operates in a single-scan, triggered mode.

Philip S. Crosby's U.S. Pat. No. 4,916,543 describes a system that uses a circular scan streak tube to record fast optical data. This system can detect and store event signal data over a time interval that is several times the period of the electron scan. It provides both averaged and slow information.

Daniel Joseph Bradley's U.S. Pat. No. 4,327,285 describes an improved method and apparatus for studying optical phenomena generated by picosecond pulses and the pulses themselves. The method involves obtaining a record of repetitive optical phenomena with durations in the picosecond or sub-picosecond range by synchronizing the deflection of the electron image in an electron-optical streaking image tube with the repetition rate of a pulse train from a continuous wave mode-locked laser that supplies such pulses to the tube. To achieve synchronization, a reference frequency signal is supplied to both the laser and the deflection electrodes in the image tube. The signal applied to the deflection electrodes may comprise a synchronized sinusoidal voltage signal and a slowly varying bias voltage signal. An optical multi-channel analyzer may be used at the output of the image tube, linked to an oscilloscope or pen recorder to provide slow information.

U.S. Pat. No. 4,327,285 by Daniel Joseph Bradley explains a better way to study optical phenomena generated by picosecond pulses and the pulses themselves. The method involves synchronizing the deflection of the electron image in an electron-optical streaking image tube with the repetition rate of a pulse train from a continuous wave mode-locked laser that supplies such pulses to the tube. This synchronization is achieved by supplying a reference frequency signal to both the laser and the deflection electrodes in the image tube. The signal applied to the deflection electrodes may comprise a synchronized sinusoidal voltage signal and a slowly varying bias voltage signal. An optical multi-channel analyzer may be used at the output of the image tube, linked to an oscilloscope or pen recorder to provide slow information. This method allows obtaining a record of repetitive optical phenomena with durations in the picosecond or sub-picosecond range.

Daniel Joseph Bradley, in U.S. Pat. No. 3,973,117 introduces an innovative electron-optical image tube that overcomes the constraints associated with conventional photographic and image storage techniques. This design facilitates the direct acquisition of a linear intensity profile for a pulse train. Unlike traditional image tubes with phosphor screens, Bradley's invention incorporates a disc featuring one or more precisely positioned slit apertures. The photoelectron image traverses these apertures in a scanning motion. By adjusting the time spacing of light pulses, synchronization occurs between the image tube's operation and the fixed apertures during a continuous circular scan.

This synchronized approach maximizes the transmission of photoelectrons through the apertures, ensuring optimal collection and multiplication by an electron multiplier positioned on the image tube's end wall. The resultant electrical signal, optionally amplified, can be recorded using instruments such as a pen recorder or oscilloscope. The technology in Bradley not only enables the detection of event signals but also allows for the storage of data over a time interval several times the period of the electron scan. Consequently, the system provides a means to capture and analyze slow information, marking a significant advancement in image tube technology.

Yutaka Tsuchiya's U.S. Pat. No. 4,611,920 introduces an electron tube device designed to measure the exceedingly faint intensity of light. The innovation lies in the method of superimposing multiple streaking images of light beams, arising from fluorescence within a phosphor layer impacted by secondary electrons at the level of single photon units. This process involves the formation of streaking images through secondary electrons generated within a specialized streaking tube. Here, electrons produced in a photoelectric layer undergo acceleration towards the phosphor layer while passing through a microchannel plate.

The resultant superimposed streaking images, exhibiting heightened brightness, are then captured by a television camera. Tsuchiya's invention, represents a pivotal advancement in the ability to discern and quantify extremely low light intensities. This device captures and amplifies the subtle nuances of light through a sophisticated interplay of electron interactions, providing a mechanism for obtaining detailed information at extremely diminished intensity levels, thus contributing significantly to the domain of slow information acquisition.

In U.S. Pat. No. 4,694,154 Yutaka Tsuchiya discloses an electron tube device crafted for the measurement of light pulses at a high repetition rate. This inventive apparatus comprises an electron tube housed within an evacuated envelope, featuring an arranged assembly of components including a photocathode, focusing electrode, deflection electrodes, slit electrode, dynodes, and a collector electrode. The integral power supply device plays a pivotal role, providing voltages to the dynodes, focusing electrode, and slit electrode, while the deflection voltage generator, operating in conjunction, supplies precise deflection voltages to the deflection electrodes.

The unique aspect of Tsuchiya's design lies in the orchestrated synchronization between the changing phases of deflection voltages and the arrival of light pulses on the photocathode. This synchronized phase modulation enables the sequential sampling of discrete portions of the light pulses. This advancement not only demonstrates technological sophistication but also represents a substantial leap in the field of high-repetition-rate light pulse measurement. The apparatus, by virtue of its ability to selectively sample different segments of light pulses, offers a precise and nuanced approach to capturing information in environments characterized by rapid repetition. In summary, this invention presents a valuable and patent-worthy solution for the precise measurement of light pulses occurring at high frequencies, contributing significantly to the acquisition of detailed information in dynamic and high-frequency scenarios.

In the utilization of a streak camera employing the repetitive mode identified as “synchroscan,” an exceptional temporal resolution of 2 picoseconds (full width at half maximum—FWHM) can be achieved over extended time exposures exceeding one hour. This capability is realized through calibration, as detailed in the work of Wilfried Uhring et al., titled “Very High Long-Term Stability Synchroscan Streak Camera,” published in the Review of Scientific Instruments (Rev. Sci. Instrum.) 74 (2003) 2646. Uhring's methodology ensures prolonged stability and precision in temporal resolution, establishing a notable advancement in the field of streak camera technology for extended-duration observations.

In the early 1980s, the detection of Cherenkov radiation was accomplished through the use of a synchroscan circular streak camera, as documented by A. E. Huston and K. Helbrough in their work titled “The Synchroscan Picosecond Camera System,” published in the Philosophical Transactions of the Royal Society of London A298 (1980) 287-293. However, despite their ability to capture high-speed physical phenomena with precision, commercially available streak cameras are limited in their capacity to convey received temporal information in the form of nanosecond signals—a key feature employed in scientific experiments utilizing PMTs, APDs, SiPMs, and HPDs.

This limitation has hindered the widespread application of commercial streak cameras in various fields, including nuclear medicine, optical microscopy, and high-energy particle and nuclear physics experiments. Addressing this challenge for circular scan impact cameras, Amur Margaryan et al., in their U.S. Pat. No. 8,138,450 titled “Radio Frequency Phototube” present a solution. This inventive device exhibits the capability to extract spatial coordinates of scanned electrons as nanosecond signals, thereby expanding the utility and versatility of circular scan streak cameras in diverse scientific and technical applications.

The time resolution of the RF Timer is determined by a combination of various physical phenomena and the specific technical parameters inherent to the device (R. Carlini, N. Grigoryan, O. Hashimoto, S. Knyazyan, S. Majewski, A. Margaryan, G. Marikyan, L. Parlakyan, Y. Popov, L. Tang, H. Vardanyan, C. Yan, “Proposal for Photon Detector with Picosecond Time Resolution,” Yerevan Physics Institute and Stanford Linear Accelerator, NATO ADVANCED RESEARCH WORKSHOP “Advanced Photon Sources and Their Applications,” Nor Hamberd, Armenia, Aug. 29-Sep. 2, 2004).

### SUMMARY OF THE INVENTION

The present invention discloses a novel method and apparatus designed for the precise detection of single electrons and photons, coupled with an unparalleled capability to determine recording times with picosecond accuracy. More specifically, the invention discloses the groundbreaking time resolution of 10 picoseconds and an exceptional stability of 0.2 ps/h for single photons in a synchronous mode experiment, using a picosecond laser. These results highlight the potential of the RF Timer to achieve unprecedented precision in photon timing applications, which could lead to significant advancements in various scientific and technological fields.

The object of the present invention is a method and apparatus for detecting single electrons and photons and determining the recording time with picosecond accuracy. The RF Timer is an integral component endowed with the unique ability to operate with continuous flows of electrons or photons, transforming them into rapid nanosecond electronic signals akin to those produced by PMTs, SiPMs, APDs or HPDs. The result is the availability of data corresponding to individual electrons or photons, ready for further processing through advanced high-speed nanosecond electronic systems. This groundbreaking approach not only advances the precision of single-particle detection but also facilitates seamless integration with cutting-edge nanosecond electronics, heralding a new era in high-accuracy, high-speed data acquisition and processing for electron and photon detection applications.

In another embodiment, the present invention provides a method and apparatus introduced to facilitate the comprehensive investigation of optical and related phenomena initiated by picosecond pulses, including a focused exploration of the pulses themselves. Beyond enabling fundamental scientific measurements across diverse domains such as physics, chemistry, and biology, the disclosed method and apparatus extend their applicability to encompass crucial sectors like quantum technologies, nanoscience, medical imaging, and optical communications. This innovation proves particularly advantageous in scenarios where phenomena unfold within the picosecond domain and at exceptionally high repetition rates reaching up to gigahertz frequencies. The adaptability of the present invention to such wide-ranging applications marks a significant stride in advancing research, diagnostics, and communication technologies across various scientific and industrial disciplines.

In another embodiment, a specific objective is to introduce a configuration wherein the RF phototube serves the purpose of detecting individual photoelectrons or secondary electrons. This arrangement is designed to culminate in the accumulation of data at the output end of the tube, presented as nanosecond electronic signals. The innovation's focus on single-particle detection and efficient data aggregation through nanosecond electronic signals enhances the overall precision and speed of the RF phototube, offering a robust solution for applications demanding high-speed electron detection and data acquisition.

Yet in another embodiment, an apparatus is furnished where a circular scan RF Timer is employed for the electronic documentation of physical phenomena occurring within the picosecond range, induced by continuous bursts of photons or other particle pulses lasting in the order of picoseconds. This apparatus not only facilitates the identification of such physical phenomena with picosecond resolution but also allows for the precise temporal correlation of electronic signals with picosecond accuracy. The synchronized operation of circular scan RF Timers with the frequencies of the original photon or particle beams enables the reproduction of consecutive events, thus facilitating the detection and analysis of rare phenomena within the picosecond timeframe.

The synchronized operation of multiple RF Timers enables the measurement of time intervals between distinct physical phenomena with picosecond precision. Specifically, multiple RF Timers can operate synchronously with picosecond resolution. It is noteworthy that the data output from the RF Timer is presented in the form of nanosecond electrical signals, readily amenable to processing and digitization using contemporary high-speed electronics, achieving speeds of up to 5 MHz. This collective functionality not only broadens the scope of applications but also underscores the versatility and efficiency of the circular scan RF Timer in capturing and analyzing events at the picosecond scale.

The crux of the invention lies in the RF Timer orchestrated for the precise control of single electrons and photons within a vacuum container. This container houses key components, including:
(i). An electron gun featuring a photocathode for the conversion of light pulses emanating from a continuous stream of photons or particles into photoelectrons. Additionally, an electron-transparent accelerating electrode is employed to propel the photoelectrons to several kilo electron volts (keV).
(ii). An electrostatic lens positioned after the accelerating electrode, serving to focus the accelerated electrons onto the recording device.
(iii). A deflecting electrode, is situated after the electrostatic lens in the trajectory of the photoelectrons generated by light pulses. This electrode facilitates the deflection of photoelectrons along a circular path.
(iv). A position-sensitive recording system includes double microchannel plates arranged in a chevron configuration and a delay line anode. Positioned after the specified deflecting electrode this recording system captures and records the photoelectrons, providing detailed information about their positions. This information is presented in the form of nanosecond electronic signals, seamlessly processed by nanosecond electronics. This distinctive design ensures accurate control and measurement of single electrons and photons, paving the way for high-precision applications in numerous scientific and technological domains.

The determination of recording times for single electrons with keV energy is achieved through a methodical process. Initially, focused electrons undergo deflection as they traverse a specifically designed deflecting electrode, influenced by high-frequency radio waves applied to the electrode. The deflected electrons are subsequently captured by a coordinate-sensitive recorder positioned at a defined distance from the deflecting electrode. This capturing results in the generation of nanosecond-long electrical signals. These signals are processed by high-speed electronics, facilitating the precise determination of the coordinates associated with each recorded electron.

Fundamentally, the coordinate obtained is in one-to-one correspondence with one of the phases of the applied radio wave. This correspondence establishes a direct relationship, enabling the determination of the time associated with each recorded electron. The innovative synergy between the deflecting electrode, high-frequency radio waves, and the coordinate-sensitive recorder, coupled with the advanced processing capabilities of high-speed electronics, underscores the efficacy of this method in accurately determining the recording times of single electrons with keV energy. This unique approach presents valuable applications across a spectrum of high-precision scientific and technological endeavors.

The determination of registration times for single photons unfolds through a systematic process. Initially, photons impinge upon a dedicated photocathode crafted for this specific purpose. Upon contact, these photons undergo transformation into photoelectrons. Subsequently, these photoelectrons are accelerated to several keV, precisely focused, and their registration times are subsequently ascertained using the method applied for electron registration. This inventive sequence of operations ensures an accurate and efficient determination of registration times for single photons, demonstrating a comprehensive and integrated approach within the realm of photon detection and timing.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 exemplarily illustrates a Radio Frequency Timer.

FIG. 2 exemplarily illustrates the Synchroscan operation mode.

FIG. 3 exemplarily illustrates the Radio Frequency Timer in a Spiral Scanning operation mode.

### DETAILED DESCRIPTION OF THE INVENTION

The present invention is best understood by reference to the detailed description and examples set forth herein.

Embodiments of the invention are discussed below with reference to the examples. However, those skilled in the art will readily appreciate that the detailed description given herein with respect to these examples is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications described herein, as these may vary. It is also to be understood that the terminology used herein is used for the purpose of describing particular embodiments only and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention.

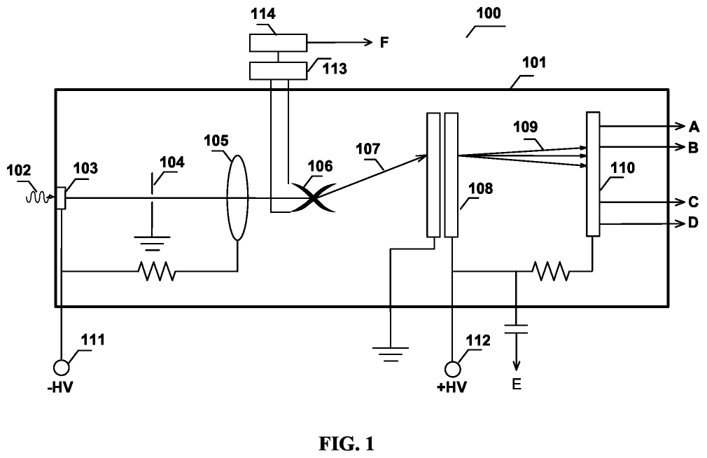

Referring to FIG. 1, the present invention discloses an RF Timer 100 including a vacuum container 101, a photocathode 103, a photoelectron 103, an accelerating electrode 104, an electrostatic lens 105, an electron multiplier based on microchannel plates (MCP) 108, an RF source 107, an RF deflector 106, a multiplier derived electrons 109, a coordinate sensitive anode based on delay line 110, and a high voltage source 111 and 112.

The RF Timer 100 includes a scanning system that is capable of providing a continuous high-speed data stream that responds to continuous streams of electrons or photons in the form of fast electronic signals of nanosecond duration, such as signals from the PMT, APD, SiPM or HPD detectors, so that data corresponding to the picosecond time domain of single electrons or photons is available for further processing.

In one embodiment, the RF Timer 100 is configured to encompass a series of critical components. This includes a dedicated photocathode 103, a photoelectron accelerator system 104, an electrostatic lens 105 focusing system, and a sensitive, helical shape RF deflector 106, capable of properly operating in the range 500-1000 MHz.

In one embodiment this deflector facilitates a circular scanning of 2.5 keV energy electrons. At the terminus of the device, precisely aligned with the focus of the electrostatic lens 105, resides a coordinate-sensitive detector including microchannel plates 108 and delay-line anode 110. This detector plays a pivotal role in detecting and determining the coordinates of the electrons scanned during the process. The comprehensive integration of these components within the RF Timer ensures an efficient and precise mechanism for recording photons, marking a significant advancement in the field of high-speed, high-precision photon detection and data acquisition.

The scanning system of the RF Timer demonstrates exceptional sensitivity, registering at approximately 1 mm/V deflection for 2.5 keV electrons. This efficiency allows for the attainment of a circular scan spanning approximately 2 cm in diameter, requiring about 1 Watt of RF power for optimal operation (Gevorgian, L., Ajvazyan, R., Kakoyan, V., Margaryan, A., & Annand, J. R. M., 2015, “A radio frequency helical deflector for keV electrons”, Nuclear Instruments and Methods in Physics Research Section A: Accelerators, Spectrometers, Detectors and Associated Equipment, 785, 175-179). Under these specified conditions, the induced RF noise level remains below 10 mV, ensuring a high signal-to-noise ratio. Notably, the signals obtained from single electrons can reach 100 mV or more, allowing for seamless processing without encountering any significant challenges. This combination of sensitivity, precision, and low noise levels reinforces the RF Timer's efficacy for reliable and high-performance photon and electron detection, exemplifying a notable advancement in the realm of radio frequency scanning systems.

High-voltage DC 111 and 112 devices serve as the power source, providing voltages to key components within the system. These components include the accelerating electrode 104, the electrostatic focusing lens 105, the MCP 108 and the anode based on delay line 110 are responsible for registering the positions of the scanned electrons.

A sinusoidal voltage operating at 500 MHz is applied to the RF deflector 106 (a preferable frequency range for the RF Timer is 500-1000 MHz), showcasing the system's adaptability to high-frequency operations. The RF deflector 106 also exhibits the capability to operate seamlessly in synchronization with RF-modulated light sources and/or other RF Timers, further expanding its utility and versatility within a networked or modular configuration. This comprehensive power and control arrangement features the robust and flexible nature of the system, making it a valuable solution for varied applications in high-speed electron detection and photon recording.

Diverging from conventional image storage techniques and integrated output devices like streak cameras, the RF Timer introduces a paradigm shift by incorporating a high-speed, single-electron position-sensitive detector. This innovative detector yields nanosecond signals akin to traditional photomultipliers. This integration positions the RF Timer to harness the collective advantages of streak cameras and conventional photomultipliers, emerging as an unparalleled single-electron or photon-sensitive detector characterized by picosecond time resolution. Its application extends notably to research reliant on single photon recording, encompassing domains such as Cherenkov radiation observation in high-energy particle and nuclear physics experiments (Amur Margaryan, Robert Ajvazyan, Simon Zhamkochyan, John Annand, Picosecond photon detectors for the LHC, Acta Physica Polonica B 7 (4) (2014) 759-766; A. Margaryan, J. R. M. Annand, P. Achenbach, et al., High precision momentum calibration of the magnetic spectrometers at MAMI for hypernuclear binding energy determination, Nucl. Instr. Meth. Phys. Res. Sect. A 846 (2017) 98-105), time-of-flight positron emission tomography (A. Margaryan, V. Kakoyan, S. Knyazyan, Time-of-flight positron emission tomography with radiofrequency phototube, Acta Physica Polonica. Ser. B 4 (1) (2011) 107-112), time-of-flight diffuse optical tomography, high-precision fluorescence microscopy, laser telemeters, and various other scientific pursuits (Ani Aprahamyan, Amur Margaryan, Vanik Kakoyan et al., Advanced Radio Frequency Timing AppaRATus (ARARAT) Technique and Applications, arXiv-2211.16091, 2022). This advancement marks a transformative leap in photon and electron detection technology, enhancing precision and versatility across a spectrum of research endeavors.

FIG. 1 is an exemplary illustration of a Radio Frequency Timer.

The RF Timer in FIG. 1 is housed within a vacuum container 101 maintained under a vacuum exceeding 10⁻⁶ Torr. This includes an incident photon 102, the photocathode 103, that is positioned to receive the incident photon 102 and generate electrons upon impact. The generated photoelectrons 107 traverse an electron-transparent accelerating electrode 104 before passing through the electrostatic lens 105. The electrostatic lens 105 precisely focuses the electrons onto the registering plane the electron multiplier plates 108 and position sensitive anode 110, located at the timer's terminus.

The photoelectrons 107 generated from the photocathode 103 pass through an electron-transparent accelerating electrode 104. Then through the electrostatic lens 105, which focuses the electrons onto the plane of the register (the electron multiplier based on microchannel plates 108 and position sensitive anode 110) placed at the end of the timer. Before that, the electrons 107 pass through the RF deflection electrode 106 which is powered by the RF source 113. The recording device includes microchannel plates 108. The microchannel plates 108 can be arranged in different patterns such as a chevron pattern. Single electrons in that system are multiplied more than 10⁶ times. The resulting electron beam (the multiplier-derived electrons 109, are directed to the coordinate-sensitive electrode 110 based on delay line which is placed at a distance of about 5 mm from the register microchannel plates 108.

Four position-sensitive, nanosecond-duration electrical signals A, B, C, and D are generated in that electrode, which are drawn out of the vacuum. Those signals are processed out of the vacuum container 101, digitized with high-speed electronics, and stored. These digitized signals are then used to determine the coordinates of the scanned electrons (photoelectrons 107) on the register plane (the electron multiplier based on microchannel plates 108). This comprehensive system underscores its potential for achieving unparalleled precision in tracking electrons and photons, opening avenues for groundbreaking applications in diverse scientific disciplines.

The coordinate of a single electron can be determined with a resolution of about 200 μm, which is equivalent to a time resolution of about 4 ps for a 500 MHz driven RF Timer. An E and F signals extracted from the microchannel plates 108 and master oscillator 114 provides information about the zero time of the device and start time of the RF Timer with an accuracy of a few 100 ps. The RF Timer serves as a simple, easy-to-use, high-speed single photon detector and timing processor.

The high voltage devices 111 and 112 supply the necessary voltages to the electrodes of the RF Timer. More specifically −2.5 kV and +3.0 kV voltages are applied to the electron accelerator 104, focusing on the electrostatic lens 105 and recording on the electron multiplier based on microchannel plates 108 and 110, respectively.

### Synchroscan Operation Mode

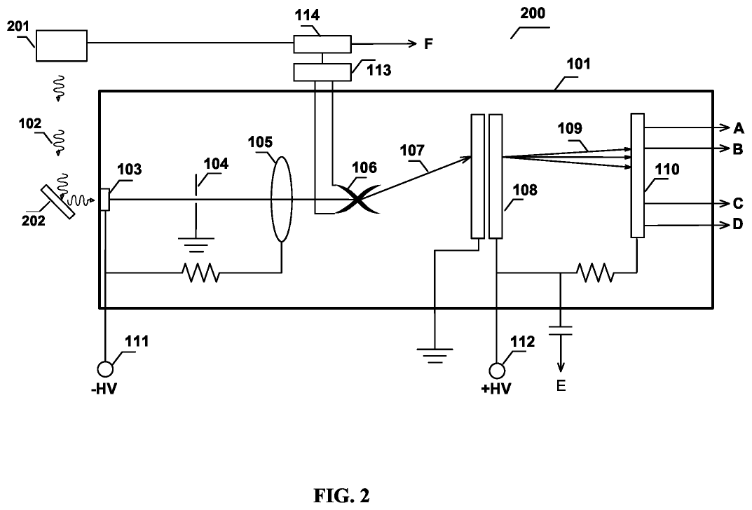

FIG. 2 is an exemplary illustration of the synchroscan operation mode added to the RF Timer in FIG. 1.

In another embodiment, shown in FIG. 2, the RF Timer has a synchroscan mode added to the RF Timer. FIG. 2 showcases the synchroscan mode components that include an RF synchronized photon source 201, and a mirror 202, that directs the photon beam into the RF Timer. This allows for the adjustment of the circular scan rate to align with—either precisely or in multiples or sub-multiples—the repetition rate of light or particle pulses within the pulse train originating from the continuous source of repetitive light or particle pulses (the incident photon 102). Hence, the photoelectron image of each light pulse always will coincide with the fixed spot on the scanned circle.

The periods of the photon (or particle) source and the RF Timer are phase-locked, therefore, the photoelectron or secondary electron image with a fixed time, from the incident light or particle pulses (incident photons 102) or from the experiment induced by incident light or particle pulses always will coincide with the fixed spot on the scanned circle.

Such an operating feature can be used in the case the device is used to detect delayed events produced in intense beams. For example, time-resolved fluorescence imaging or diffuse optical tomography.

The coordinated operation of the optical frequency comb (S. A. Diddams, J. Ye, L. Hollberg “Femtosecond lasers for optical clocks and low noise frequency synthesis,” in Femtosecond Optical Frequency Comb: Principle, Operation and Applications, S. Cundiff and J. Ye, Eds. New York: Springer-Verlag, 2004 and Th. Udem, R. Holzwarth, Th. Haensch “Femtosecond optical frequency combs,” Eur. Phys. J. Special Topics 172 (2009) 69), and RF Timer respectively, enables the attainment of superior time resolution exceeding 10 ps and remarkable stability of better than 0.01 ps/h in a single photon counting system (A. Margaryan, “Radio frequency phototube and optical clock: High resolution, high rate and highly stable single photon timing technique,” Nucl. Instr. & Meth. in Physics Research Section A652(1):504-507). This innovation holds significant promise for applications in single-photon-based research scenarios where precise recording of photon times is imperative. Potential applications span diverse fields including high precision comparison of optical clocks (A. Margaryan, Optical. clock, Radio frequency timing technique and a new Earth-bounded gravitational redshift experiment, Armen. J. Phys. 3 (1) (2010) 33-44., V. G. Gurzadyan, A. T. Margaryan, Ultrahigh accuracy time synchronization technique operation on the moon, Euro. Phys. J. Plus 136 (3) (2021) 329), Cherenkov radiation recording in high-energy elementary particle and nuclear physics experiments, time-of-flight diffuse optical tomography, fluorescence ultra-precision optical microscopes, laser telemeters, and more. The synchronous and high-resolution capabilities of this system position it as a pioneering solution for advancing precision photon recording in a multitude of scientific and technological applications.

### Spiral Scanning Operation Mode of the RF Timer

The circular scanning has a limited time range, the inverse of the RF frequency, which in the case of 500 and 1000 MHz is equal to 2 ns and 1 ns, respectively. This is usually orders of magnitude shorter than the period of light pulses which is the same as a period of master oscillator.

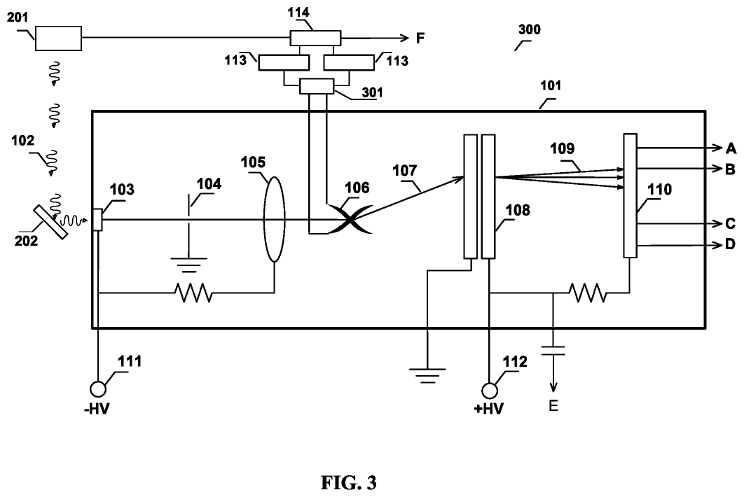

In another embodiment, shown in FIG. 3 illustrates a spiral scan mode, that includes a vacuum container 101, an incident photon 102, a photocathode 103, an accelerating electrode 104, electrostatic lens 105, RF deflector 106, photoelectron 107, microchannel plates 108 based electron multiplier, a multiplied electrons 109, a delay line based position sensitive anode 110, a high voltage source 111 and 112, a RF synthesizer 113, a RF master oscillator 114, a RF synchronized photon source 201, a mirror 202, a RF power combiner 301, coordinate sensitive signals from delay line anode A, B, C, D, a time-zero signal E from microchannel plates 108 based electron multiplier, and a start signal F from master oscillator 114.

Operating the helical deflector by using two different frequencies, the resulting “beat” in deflection amplitude produces a spiral pattern rather than a circle. The time range to complete a spiral cycle (the inverse of the beat frequency) is increased consequently and can be equalized to the period of the master oscillator 114. Time resolution in this case in the whole-time interval will be practically the same order as in the case of circular scanning. Those two frequencies are phase locked and come from the same master oscillator 114.

The spiral scanning operation mode facilitates the utilization of the primary microchannel plates 108, enhancing both the rate capability and overall lifespan of the device. This innovative approach to extending the temporal range through spiral scanning is applicable not only to the current device but can also be effectively employed in streak cameras. This adaptability significantly broadens the potential application fields of streak cameras, offering a notable enhancement in their functionality and versatility.

Combination of the RF Timer and Regular Timing technique

The combination of the RF Timer and conventional timing techniques, which can be implemented using the microchannel plates-based electron multiplier's time-zero-E and master oscillator's 114 start-F signals, opens up new possibilities in single electron and photon timing technologies. Usually, the frequency of the master oscillator 114 is in the range of several tens of MHz, from which high frequencies located in the range 500-1000 MHz are synthesized to operate the RF Timer. Therefore, by measuring the difference between the E and F signals, with an accuracy of several 100 ps, it is possible to determine for each recorded electron or photon the number of high-frequency periods that occurred in this time interval. This provides the ability to have the same higher time resolution over the entire time range as provided by the RF Timer.

In addition, by recording the number of periods of the master oscillator 114 frequency, we have a high-resolution, continuous, timing technique for single electrons and photons. This feature is applicable for the cases described in FIG. 1, FIG. 2 and FIG. 3 and in general for other type position sensitive detectors as well.

While the present invention has been described in connection with what are presently considered to be the most practical and preferred embodiments, it is to be understood that the present invention is not limited to these herein disclosed embodiments. Rather, the present invention is intended to cover all of the various modifications and equivalent arrangements included within the spirit and scope of the appended claims.

Although specific features of various embodiments of the invention may be shown in some drawings and not in others, this is for convenience only. In accordance with the principles of the invention, the feature(s) of one drawing may be combined with any or all of the features in any of the other drawings. The words “including”, “comprising”, “having”, and “with” as used herein are to be interpreted broadly and comprehensively and are not limited to any physical interconnection. Moreover, any embodiments disclosed herein are not to be interpreted as the only possible embodiments. Rather, modifications and other embodiments are intended to be included within the scope of the appended claims.

We claim:

1. An apparatus for an RF Timer in a high vacuum system, comprising:
a photocathode to convert light pulses from a continuous stream of photons into photoelectrons;
an accelerating electrode to accelerate the photoelectrons to a particular number of electron volts;
an electrostatic lens to focus the photoelectrons;
a deflecting electrode for providing a trajectory deflection of the photoelectrons generated by the light pulses;
a microchannel plate to multiply the deflected photoelectrons; and
a position-sensitive detector to record the position.

2. The apparatus of claim 1, wherein the microchannel plate comprises of two microchannel plates in a chevron pattern.

3. The apparatus of claim 1, wherein the position-sensitive detector comprises a delay line-based position-sensitive anode, wherein the position-sensitive anode receives the multiplied electrons from the microchannel plate and records the positions of the photoelectrons.

4. The apparatus of claim 1, wherein the trajectory deflection is a circular trajectory deflection.

5. The apparatus of claim 1, wherein the trajectory deflection is a spiral trajectory deflection.

6. The apparatus of claim 1, wherein the photocathode converts light pulses from a laser to photoelectrons.

7. The apparatus of claim 1, wherein the position-sensitive detector is positioned below the deflection electrode.

8. The apparatus of claim 1, wherein the electrostatic lens is positioned after the accelerating electrode.

9. An apparatus for an RF Timer in a high vacuum system, comprising:
a synchroscan operation mode for synchronizing the photons with the RF Timer;
a photocathode to convert electrons to photons;
an accelerating electrode to accelerate the photoelectrons to a particular number of electron volts;
an electrostatic lens to focus the accelerated photoelectrons;
a deflecting electrode for providing a trajectory deflection of the photoelectrons;
a microchannel plate to multiply the deflected photoelectrons; and
a position-sensitive detector to record the position of the photoelectrons on a position sensitive detector.

10. The apparatus of claim 9, wherein the synchroscan operation mode phase locks the photons with the RF Timer.

11. The apparatus of claim 9, wherein the particular number of electron volts is 2.5 kilo electron volts.

12. A method for an RF Timer in a high vacuum system, comprising:
converting light pulses from a continuous stream of photons to photoelectrons;
accelerating the photoelectrons to a particular number of electron volts;
focusing the accelerated photoelectrons;
deflecting the accelerated photoelectrons in a trajectory;
receiving and multiplying the photoelectrons in microchannel plates;
recording the position of the photoelectrons on a position sensitive detector.

13. The method of claim 12 further comprising synchronizing the photons with the RF Timer.

14. The method of claim 12, wherein the microchannel plates comprises of a double microchannel plates in a chevron pattern.

15. The method of claim 12, wherein the trajectory deflection is a circular trajectory deflection.

16. The method of claim 12, wherein the trajectory deflection is a spiral trajectory deflection.
